(19) United States
(12) Patent Application Publication
(10) Pub. No.: US 2024/0251623 A1
(43) Pub. Date: Jul. 25, 2024

(54) DISPLAY APPARATUS

(71) Applicant: LG Display Co., Ltd., Seoul (KR)

(72) Inventors: SeoHyun NAM, Paju-si (KR); SeHong PARK, Paju-si (KR); Wonrae KIM, Paju-si (KR); Inae CHOI, Paju-si (KR); Sejong SEONG, Paju-si (KR)

(73) Assignee: LG Display Co., Ltd., Seoul (KR)

(21) Appl. No.: 18/521,814

(22) Filed: Nov. 28, 2023

(30) Foreign Application Priority Data
Jan. 25, 2023 (KR) 10-2023-0009237

(51) Int. Cl. H10K 59/35; H10K 50/15; H10K 50/16; H10K 59/122; H10K 59/80

(52) U.S. Cl. CPC H10K 59/351; H10K 50/15; H10K 50/16; H10K 59/122; H10K 59/873

(57) ABSTRACT

Discussed is a display apparatus including at least one pixel on a substrate and having a plurality of subpixels, a pattern portion disposed on the substrate and formed to be concave between the plurality of subpixels, and a reflective portion on the pattern portion. The plurality of subpixels include a first layer having a plurality of concave portions adjacent to the reflective portion and an organic light emitting layer having a lower organic layer on the first layer and a light emitting layer on the lower organic layer, and light efficiency of light emitted from the light emitting layer and output to the substrate through a concave portion of the plurality of concave portions is proportional to a thickness change value of the lower organic layer.

### CROSS-REFERENCE TO RELATED APPLICATIONS

This application claims priority to Korean Patent Application No. 10-2023-0009237 filed in the Republic of Korea on Jan. 25, 2023, the entire contents of which is hereby expressly incorporated by reference into the present application.

### BACKGROUND

### Field of the Invention

The present disclosure relates to a display apparatus for displaying an image.

### Discussion of the Related Art

Among display apparatuses, an organic light emitting display apparatus has many advantages such as a high response speed and low power consumption, does not require a separate light source unlike a liquid crystal display apparatus, and self-emits light to be individually driven for each pixel. Also, the organic light emitting display apparatus can implement perfect or clearer black color, and thus, the organic light emitting display apparatus has received attention as a next-generation flat panel display apparatus.

The organic light emitting display apparatus displays an image through light emission of a light emitting element layer. The light emitting element layer can include a light emitting layer interposed between two electrodes.

Meanwhile, light extraction efficiency of the organic light emitting display apparatus can be reduced as some of light emitted from the light emitting element layer is not emitted to the outside due to total reflection on the interface between the light emitting element layer and an electrode and/or between a substrate and an air layer.

### SUMMARY OF THE DISCLOSURE

The present disclosure has been made in view of the above problems and it is an object of the present disclosure to provide a display apparatus that can improve light extraction efficiency of light emitted from a light emitting element layer.

It is another object of the present disclosure to provide a display apparatus in which light extraction efficiency can be maximized.

It is still another object of the present disclosure to provide a display apparatus in which light extraction efficiency can be further improved through light extraction from a non-light emission area.

It is further still another object of the present disclosure to provide a display apparatus that can reduce power consumption.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include a first layer including a plurality of concave portions adjacent to the reflective portion and an organic light emitting layer having a lower organic layer on the first layer and a light emitting layer on the lower organic light emitting layer, light efficiency η_{best} of light emitted from the light emitting layer and output to the substrate through the concave portion satisfies η_{best}=0.7Δd−2.37 m+97.684, where Δd is a thickness change value of the lower organic layer, and ‘m’ is a hierarchical value of a light efficiency trend with respect to Δd.

In accordance with another aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include a first layer including a plurality of concave portions adjacent to the reflective portion and an organic light emitting layer having a lower organic layer on the first layer and a light emitting layer on the lower organic light emitting layer, and light efficiency of light emitted from the light emitting layer and output to the substrate through the concave portion is proportional to a thickness change value of the lower organic layer.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic plan view illustrating one pixel shown in FIG. 1;

FIG. 3 is a schematic cross-sectional view taken along line I-I′ shown in FIG. 2;

FIG. 4A is a schematic view illustrating a light path of a display apparatus not having a light extraction portion according to a comparative example;

FIG. 4B is a schematic view illustrating a light path of a display apparatus according to one embodiment of the present disclosure;

FIG. 5 is a schematic enlarged view illustrating an organic light emitting layer in a portion A shown in FIG. 3;

FIG. 6 is a simulation graph illustrating light efficiency based on a thickness change of a lower organic layer of a display apparatus according to one embodiment of the present disclosure;

FIG. 7A is a light efficiency map based on a thickness of a lower organic layer, an aspect ratio of a concave portion and a radius of the concave portion of a display apparatus according to one embodiment of the present disclosure; and

FIG. 7B is a light efficiency map based on a thickness of an upper organic layer, an aspect ratio of a concave portion and a radius of the concave portion of a display apparatus according to one embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part can be added unless ‘only’ is used. The terms of a singular form can include plural forms unless referred to the contrary.

In construing an element, the element is construed as including an error range although there is no explicit description. In describing a position relationship, for example, when a position relation between two parts is described as ‘on’, ‘over’, ‘under’, and ‘next’, one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms.

These terms are only used to distinguish one element from another. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation, and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, the example embodiments of the present disclosure will be described in detail with reference to the accompanying drawings.

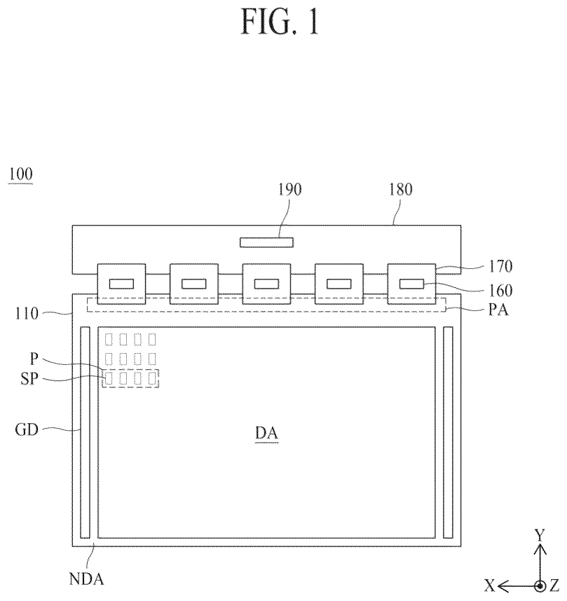

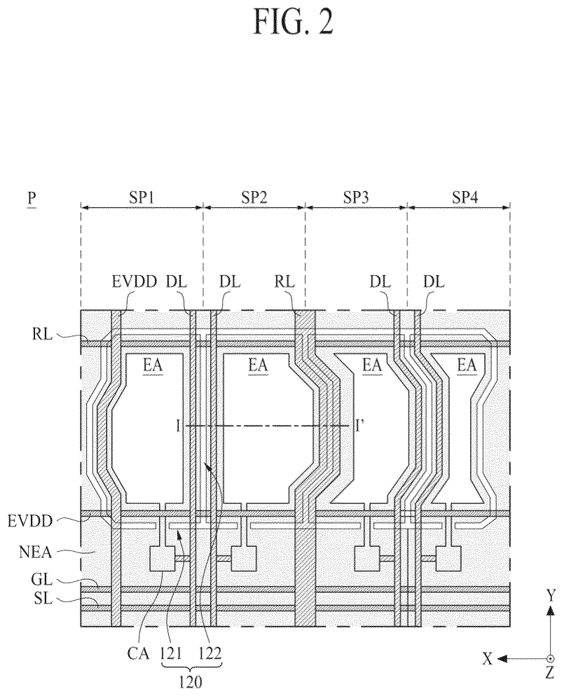

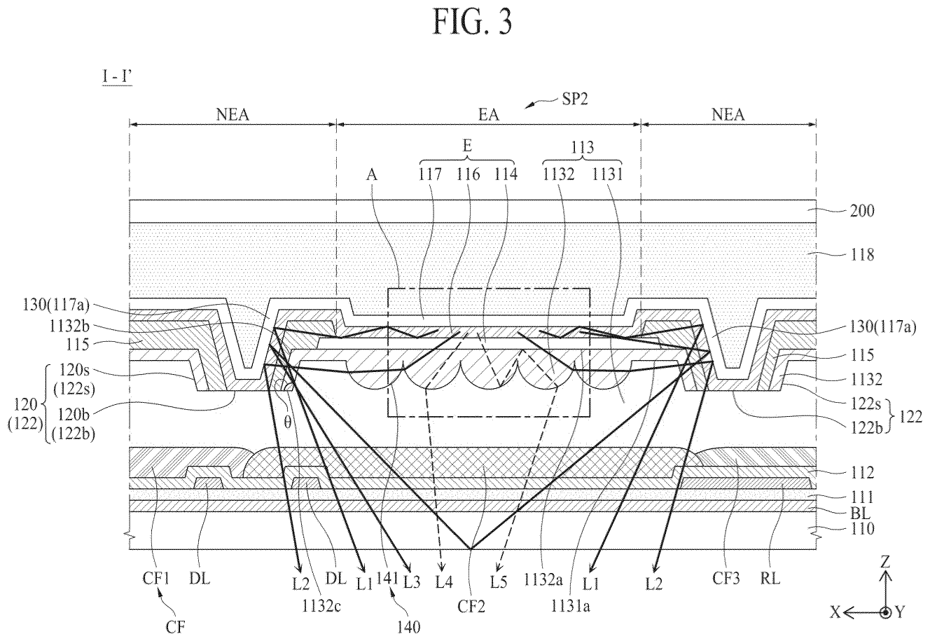

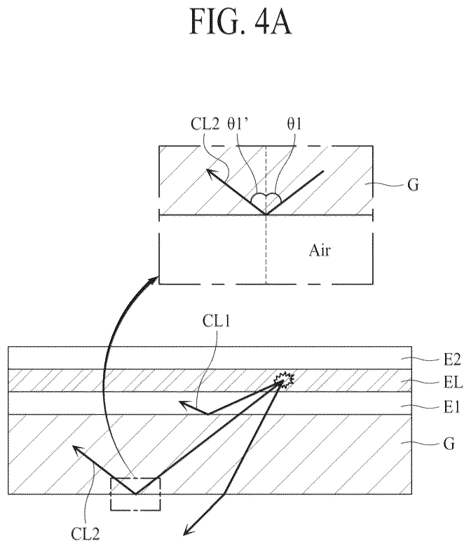

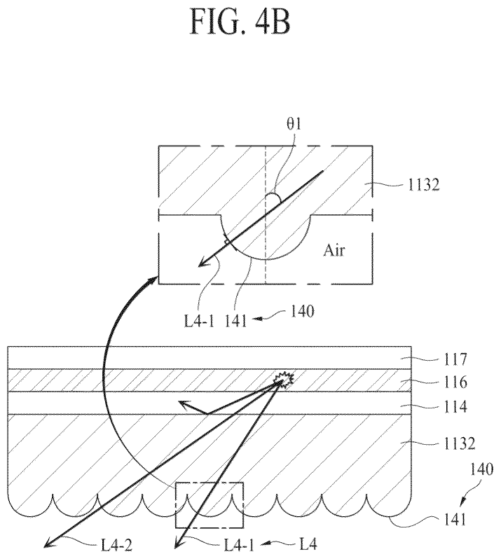

FIG. 1 is a schematic plan view illustrating a display apparatus according to one embodiment of the present disclosure, FIG. 2 is a schematic plan view illustrating one pixel shown in FIG. 1, FIG. 3 is a schematic cross-sectional view taken along line I-I′ shown in FIG. 2, FIG. 4A is a schematic view illustrating a light path of a display apparatus not having a light extraction portion according to a comparative example, and FIG. 4B is a schematic view illustrating a light path of a display apparatus according to one embodiment of the present disclosure. All components of each display apparatus according to all embodiments of the present disclosure are operatively coupled and configured.

Referring to FIGS. 1 to 4B, a display apparatus 100 according to one embodiment of the present disclosure includes a substrate 110 having a plurality of pixels P having a plurality of subpixels SP, a pattern portion 120 disposed on the substrate 110 and formed to be concave between the plurality of subpixels SP, and a reflective portion 130 on the pattern portion 120.

The plurality of subpixels SP can include a first layer 1131 including a plurality of concave portions 141 adjacent to a reflective portion 130 and an organic light emitting layer 116 having a lower organic layer 116a on the first layer 1131 and a light emitting layer 116b on the lower organic layer 116a. The organic light emitting layer 116 is an area from which light is emitted, and can be included in a light emitting element layer E that includes a pixel electrode 114 and a reflective electrode 117. The organic light emitting layer 116 can be disposed between the pixel electrode 114 and the reflective electrode 117.

Light efficiency η_{best} of light emitted from the light emitting layer 116b (or the organic light emitting layer 116) and output to the substrate 110 through the concave portion 141 can satisfy an equation such as η_{best}=0.7Δd−2.37 m+97.684. ‘Δd’ is a thickness change value of the lower organic layer 116a, ‘m’ is a hierarchical value of a light efficiency trend with respect to Δd. Meanwhile, the light efficiency η_{best} according to the above equation can refer to maximum light efficiency of light emitted from the light emitting layer 116b (or the organic light emitting layer 116) and output to the substrate 110 through the concave portion 141.

In the display apparatus 100 according to one embodiment of the present disclosure, each of the plurality of subpixels SP is provided to have a plurality of concave portions 141, so that light, which is directed toward an adjacent subpixel SP, among the light emitted from the light emitting layer 116b (or organic light emitting layer 116) can be refracted toward a light emission area of a subpixel for emitting light, whereby light extraction efficiency of the subpixel for emitting light can be improved. Further, in the display apparatus 100 according to one embodiment of the present disclosure, resonance design of the organic light emitting layer 116 (or the light emitting element layer E) can be optimized in accordance with a shape of the concave portion 141, or the shape of the concave portion 141 can be modified in accordance with the resonance design of the organic light emitting layer 116 (or the light emitting element layer E), whereby light extraction efficiency can be maximized. The resonance design improves light emission efficiency by allowing the light emitted between the pixel electrode 114 and the reflective electrode 117 to be subjected to constructive interference (or amplified) through reflection and re-reflection between the pixel electrode 114 and the reflective electrode 117, and can mean a micro cavity.

For example, in the display apparatus 100 according to one embodiment of the present disclosure, when an aspect ratio and a radius of the concave portion 141 are determined, a resonance distance can be adjusted by adjusting a thickness of the lower organic layer 116a, whereby light efficiency (or maximum light efficiency) of the light emitted from the light emitting layer 116b and output to the substrate 110 through the concave portion 141 can be improved. Therefore, the display apparatus 100 according to one embodiment of the present disclosure can be provided so that light efficiency (or maximum light efficiency) of the light emitted from the light emitting layer 116b and output to the substrate 110 through the concave portion 141 is proportional to the thickness of the lower organic layer 116a.

For another example, in the display apparatus 100 according to one embodiment of the present disclosure, when the resonance design (or resonance distance) of the organic light emitting layer 116 (or the light emitting element layer E) is determined, the shape of the concave portion 141 can be modified, so that light efficiency (or maximum light efficiency) of the light emitted from the light emitting layer 116b and output to the substrate 110 through the concave portion 141 can be improved. For example, in the display apparatus 100 according to one embodiment of the present disclosure, when the resonance distance between the pixel electrode 114 and the reflective electrode 117 is determined, the aspect ratio of the concave portion 141 and the radius of the concave portion 141 can be adjusted, whereby light efficiency (or maximum light efficiency) can be improved.

As a result, in the display apparatus 100 according to one embodiment of the present disclosure, the shape of the concave portion 141 can be adjusted (or controlled) or the resonance design of the light emitting element layer E can be adjusted (or controlled), so that light efficiency (or maximum light efficiency) of the light emitted from the light emitting layer 116b and output to the substrate 110 through the concave portion 141 can be improved. The plurality of concave portions 141 are configured to improve light extraction efficiency, and thus can be included in the light extraction portion 140.

As shown in FIG. 3, each of the plurality of concave portions 141 can be provided in the form of a parabola, and thus can be expressed as terms such as a lens, a lens structure, a parabolic and a parabolic structure.

Meanwhile, in the display apparatus 100 according to one embodiment of the present disclosure, the reflective portion 130 is provided on the pattern portion 120 formed to be concave between a plurality of subpixels SP (or in a non-light emission area NEA), so that light extraction can be performed between the plurality of subpixels SP (or in the non-light emission area NEA, whereby overall light efficiency can be improved. Therefore, in the display apparatus 100 according to one embodiment of the present disclosure, since light extraction can be performed even in the non-light emission area NEA, the display apparatus 100 according to one embodiment of the present disclosure can have the same light emission efficiency or more improved light emission efficiency even with low power as compared with a general display apparatus having no reflective portion, whereby overall power consumption can be reduced.

Referring to FIGS. 1 to 4B, each of the plurality of subpixels SP according to one example can include a light emission area EA and a non-light emission area NEA adjacent to the light emission area EA. The light emission area EA is an area from which light is emitted, and can be expressed as a term of a display area. The non-light emission area NEA is an area from which light is not emitted, and can be expressed as a term of a non-display area or a peripheral area. The pattern portion 120 according to an example can be disposed in the periphery of the non-light emission area NEA.

In the display apparatus 100 according to one embodiment of the present disclosure, the reflective portion 130 can be provided on the pattern portion 120 in the periphery of the non-light emission area NEA, whereby light, which is directed toward an adjacent subpixel SP, among the light emitted from the light emission area EA can be reflected toward the light emission area EA of a subpixel SP for emitting light. Therefore, the display apparatus 100 according to one embodiment of the present disclosure can improve light extraction efficiency of the subpixel SP for emitting light. In this case, the periphery of the non-light emission area NEA can refer to a partial area of the non-light emission area NEA spaced apart from or adjacent to the light emission area EA. For example, the periphery of the non-emission area NEA can be an area spaced apart from the light emission area EA while surrounding the light emission area EA.

The pattern portion 120 according to one example can be formed to be concave in the periphery of the non-light emission area NEA. For example, the pattern portion 120 can be formed to be concave in an overcoat layer 113 (shown in FIG. 3) on the substrate 110. The pattern portion 120 can be provided to surround the light emission area EA. The pattern portion 120 can be disposed to be spaced apart from the light emission area EA. In FIG. 2, point hatching (or shade) is to indicate a bank. The pattern portion 120 according to one example can be provided to surround the light emission area EA in the form of a slit or a trench. For example, as shown in FIG. 3, a width of the pattern portion 120 can be formed to be reduced from the reflective portion 130 toward the substrate 110. Further, the pattern portion 120 can include an area exposed without being covered by the bank 115 (shown in FIG. 3). Therefore, the pattern portion 120 can be expressed as terms such as a groove, a slit, a trench, a bank slit and a bank trench.

The reflective portion 130 according to one example can be formed to be concave along a profile of the pattern portion 120 formed to be concave in the periphery of the non-light emission area NEA, thereby being formed to be concave in the periphery of the non-light emission area NEA. For example, the reflective portion 130 can be disposed along a peripheral area. The reflective portion 130 can be made of a material capable of reflecting light, thereby reflecting light, which is emitted from the light emission area EA and directed toward the adjacent subpixel SP, toward the light emission area EA of the subpixel SP for emitting light. Since the reflective portion 130 is disposed to be inclined on the pattern portion 120 while surrounding the light emission area EA, the reflective portion 130 can be expressed as terms such as a side reflective portion and an inclined reflective portion.

Meanwhile, the display apparatus 100 according to one embodiment of the present disclosure can be implemented in a bottom emission type in which light emitted from the light emission area EA is emitted to the lower surface of the substrate 110. Therefore, in the display apparatus 100 according to one embodiment of the present disclosure, the light emitted to the lower surface of the substrate 110 can be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. Therefore, the display apparatus 100 according to one embodiment of the present disclosure can more improve light extraction efficiency than the display apparatus in which the reflective portion 130 disposed to be inclined is not provided.

Hereinafter, reference to FIGS. 1 to 4B, the display apparatus 100 according to an embodiment of the present specification will be described in more detail.

Referring to FIGS. 1 and 3, the display apparatus 100 according to one embodiment of the present disclosure can include a display panel having a gate driver GD, a light extraction portion 140 including a plurality of concave portions 141 overlapping the light emission area EA, a source drive integrated circuit (hereinafter, referred to as “IC”) 160, a flexible film 170, a circuit board 180, and a timing controller 190.

The display panel can include a substrate 110 and an opposite substrate 200 (shown in FIG. 3).

The substrate 110 can include a thin film transistor, and can be a transistor array substrate, a lower substrate, a base substrate, or a first substrate. The substrate 110 can be a transparent glass substrate or a transparent plastic substrate. The substrate 110 can include a display area DA and a non-display area NDA.

The display area DA is an area where an image is displayed, and can be a pixel array area, an active area, a pixel array unit, a display unit, or a screen. For example, the display area DA can be disposed at a central portion of the display panel. The display area DA can include a plurality of pixels P.

The opposite substrate 200 can encapsulate (or seal) the display area DA disposed on the substrate 110. For example, the opposite substrate 200 can be bonded to the substrate 110 via an adhesive member (or clear glue). The opposite substrate 200 can be an upper substrate, a second substrate, or an encapsulation substrate.

The gate driver GD supplies gate signals to the gate lines in accordance with the gate control signal input from the timing controller 190. The gate driver GD can be formed on one side of the display area DA or in the non-display area NDA outside both sides of the display area DA in a gate driver in panel (GIP) method, as shown in FIG. 1.

The non-display area NDA is an area on which an image is not displayed, and can be a peripheral area, a signal supply area, an inactive area or a bezel area. The non-display area NDA can be configured to be in the vicinity of the display area DA. For example, the non-display area NDA can be disposed to surround the display area DA.

A pad area PA can be disposed in the non-display area NDA. The pad area PA can supply a power source and/or a signal for outputting an image to the pixel P provided in the display area DA. Referring to FIG. 1, the pad area PA can be provided above the display area DA.

The source drive IC 160 receives digital video data and a source control signal from the timing controller 190. The source drive IC 160 converts the digital video data into analog data voltages in accordance with the source control signal and supplies the analog data voltages to the data lines. When the source drive IC 160 is manufactured as a driving chip, the source drive IC 160 can be packaged in the flexible film 170 in a chip on film (COF) method or a chip on plastic (COP) method.

Pads, such as data pads, can be formed in the non-display area NDA of the display panel. Lines connecting the pads with the source drive IC 160 and lines connecting the pads with lines of the circuit board 180 can be formed in the flexible film 170. The flexible film 160 can be attached onto the pads by using an anisotropic conducting film, whereby the pads can be connected with the lines of the flexible film 170.

The circuit board 180 can be attached to the flexible films 170. A plurality of circuits implemented as driving chips can be packaged in the circuit board 180. For example, the timing controller 190 can be packaged in the circuit board 180. The circuit board 180 can be a printed circuit board or a flexible printed circuit board.

The timing controller 190 receives the digital video data and a timing signal from an external system board through a cable of the circuit board 180. The timing controller 180 generates a gate control signal for controlling an operation timing of the gate driver GD and a source control signal for controlling the source drive ICs 160 based on the timing signal. The timing controller 190 supplies the gate control signal to the gate driver GD, and supplies the source control signal to the source drive ICs 160.

Referring to FIGS. 2 and 3, the substrate 110 according to an example can include the light emission area EA and the non-light emission area NEA.

The light emission area EA according to an example can include gate lines, data lines, pixel driving power lines, and a plurality of pixels P. Each of the plurality of pixels P can include a plurality of subpixels SP that can be defined by the gate lines and the data lines.

Meanwhile, at least four subpixels, which are provided to emit different colors and disposed to be adjacent to one another, among the plurality of subpixels SP can constitute one pixel P (or unit pixel). One pixel P can include, but is not limited to, a red subpixel, a green subpixel, a blue subpixel and a white subpixel. One pixel P can include three subpixels SP provided to emit light of different colors and disposed to be adjacent to one another. For example, one pixel P can include a red subpixel, a green subpixel and a blue subpixel.

Each of the plurality of subpixels SP includes a thin film transistor and a light emitting element layer E connected to the thin film transistor. Each of the plurality of subpixels can include a light emitting layer (or an organic light emitting layer) interposed between the pixel electrode and the reflective electrode.

The light emitting layers respectively disposed in the plurality of subpixels SP can individually emit light of different colors or commonly emit white light. According to one embodiment, when the light emitting layers of the plurality of subpixels SP commonly emit white light, each of a red subpixel, a green subpixel and a blue subpixel can include a color filter CF (or a wavelength conversion member CF) for converting the white light into light of another color. In this case, the white subpixel according to one example may not include a color filter.

In the display apparatus 100 according to one embodiment of the present disclosure, an area provided with a red color filter can be a red subpixel or a first subpixel, an area provided with a green color filter can be a green subpixel or a second subpixel, an area provided with a blue color filter can be a blue subpixel or a third subpixel, and an area in which the color filter is not provided can be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels can emit light with a predetermined brightness in accordance with the predetermined current.

The plurality of subpixels SP according to one example can be disposed to be adjacent to each other in a first direction (X-axis direction). The first direction (X-axis direction) can be a horizontal direction based on FIG. 2. The horizontal direction can be a direction in which a gate line GL is disposed.

A second direction (Y-axis direction) is a direction crossing the first direction (X-axis direction), and can be a vertical direction based on FIG. 2. The vertical direction can be a direction in which a data line DL is disposed.

A third direction (Z-axis direction) is a direction crossing each of the first direction (X-axis direction) and the second direction (Y-axis direction), and can be a thickness direction of the display apparatus 100.

The plurality of subpixels SP can include a first subpixel SP1, a second subpixel SP2, a third subpixel SP3 and a fourth subpixel SP4 arranged adjacent to each other in the first direction (X-axis direction). For example, the first subpixel SP1 can be a red subpixel, the second subpixel SP2 can be a green subpixel, the third subpixel SP3 can be a blue subpixel and the fourth subpixel SP4 can be a white subpixel, but is not limited thereto. However, the arrangement order of the first subpixel SP1, the second subpixel SP2, the third subpixel SP3 and the fourth subpixel SP4 can be changed.

Each of the first to fourth subpixels SP1 to SP4 can include a light emission area EA and a circuit area CA. The light emission area EA can be disposed at one side (or an upper side) of a subpixel area, and the circuit area can be disposed at the other side (or a lower side) of the subpixel area. For example, the circuit area CA can be disposed at the lower side of the light emission area EA based on the second direction Y. The light emission areas EA of the first to fourth subpixels SP1 to SP4 can have different sizes (or areas) as each other.

The first to fourth subpixels SP1 to SP4 can be disposed to be adjacent to one another along the first direction (X-axis direction). For example, two data lines DL extended along the second direction (Y-axis direction) can be disposed in parallel with each other between the first subpixel SP1 and the second subpixel SP2 and between the third subpixel SP3 and the fourth subpixel SP4. A pixel power line EVDD extended along the first direction (X-axis direction) can be disposed between the light emission area EA and the circuit area CA of each of the first to fourth subpixels SP1 to SP4. The gate line GL and a sensing line SL can be disposed below the circuit area CA. The pixel power line EVDD extended along the second direction (Y-axis direction) can be disposed at one side of the first subpixel SP1 or the fourth subpixel SP4. A reference line RL extended along the second direction (Y-axis direction) can be disposed between the second subpixel SP2 and the third subpixel SP3. The reference line RL can be used as a sensing line for sensing a change of characteristics of a driving thin film transistor and/or a change of characteristics of the light emitting element layer, which is disposed in the circuit area, from the outside in a sensing driving mode of the pixel P. The data lines, the pixel power line EVDD and the reference line can be included in the plurality of lines. The data lines can include a first data line DL for driving the first subpixel SP1, a second data line DL for driving the second subpixel SP2, a third data line DL for driving the third subpixel SP3 and a fourth data line DL for driving the fourth subpixel SP4.

The bottom surface 120b of the pattern portion 120 according to one embodiment is a surface formed to be closest to the substrate 110, or can be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 can be provided with the same or deeper depth as each of the plurality of concave portions 141. If the depth of the pattern portion 120 is lower than the depth of the concave portion 141, the area of the inclined reflection portion 130 can be reduced, and thus light extraction efficiency can be reduced. Therefore, in the display apparatus 100 according to one embodiment of the present disclosure, the depth of the pattern portion 120 can be provided to be equal to or deeper than that of the concave portion 141.

The inclined surface 120s of the pattern portion 120 can be disposed between the bottom surface 120b and the light extraction portion 140. Therefore, the inclined surface 120s of the pattern portion 120 can be provided to surround the light emission area EA or the plurality of concave portions 141. As shown in FIG. 3, the inclined surface 120s can be connected to the bottom surface 120b. The inclined surface 120s can form a predetermined angle θ with the bottom surface 120b. For example, the angle θ formed by the inclined surface 120s and the bottom surface 120b can be an obtuse angle. Therefore, a width of the pattern portion 120 can be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the light emitting element layer E (or the light emitting element layer E including the reflective portion 130) including the second layer 1132 on the first layer 1131, the bank 115 and the reflective portion 130, which are formed in a subsequent process, can be formed to be concave along the profile of the pattern portion 120. Therefore, the light emitting element layer E can be formed to be concave on the pattern portion 120 formed to be concave in the non-light emission area NEA (or the peripheral area). The light emitting element layer E formed to be concave in the pattern portion 120 can mean that it includes at least one of the pixel electrode 114, the light emitting layer 116 or the reflective electrode 117.

As shown in FIG. 3, the pattern portion 120 can be provided to surround the light emission area EA. As the pattern portion 120 is provided to surround the light emission area EA, at least a portion of the reflective portion 130 disposed on the pattern portion 120 can be provided to surround the light emission area EA. Therefore, in the display apparatus 100 according to one embodiment of the present disclosure, since light can be extracted even from the non-light emission area NEA near the light emission area EA, overall light efficiency can be improved. Therefore, the display apparatus 100 according to one embodiment of the present disclosure can have the same light emission efficiency or more improved light emission efficiency even with low power as compared with a general display apparatus having no pattern portion 120 and reflective portion 130, whereby overall power consumption can be reduced.

In addition, the display apparatus 100 according to one embodiment of the present disclosure can allow the light emitting element layer E to emit light even with low power, thereby improving lifespan of the light emitting element layer E.

Referring to FIG. 2, the pattern portion 120 can include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 can mean the pattern portion 120 disposed in a horizontal direction, and the second pattern line 122 can mean the pattern portion 120 disposed in a vertical direction.

The first pattern line 121 can include a bottom surface and an inclined surface. The second pattern line 122 can include a bottom surface 122b and an inclined surface 122s. Since each of the bottom surface and the inclined surface of the first pattern line 121 and each of the bottom surface 122b and the inclined surface 122s of the second pattern line 122 are the same as each of the bottom surface 120b and the inclined surface 120s of the pattern portion 120, their description thereof is replaced with the description of the bottom surface 120b and the inclined surface 120s of the pattern portion 120. The first pattern line 121 and the second pattern line 122 can be connected to one in the non-light emission area NEA (or the peripheral area) to surround the light emission area EA.

Meanwhile, the overcoat layer 113 can further include a second layer 1132 formed on the first layer 1131. The second layer 1132 according to an example can be further extended from the light emission area EA to the non-light emission area NEA to partially cover the inclined surface 120s of the pattern portion 120. Therefore, as shown in FIG. 3, an end 1132c of the second layer 1132 can be in contact with the bottom surface 120b of the pattern portion 120. In this case, the end 1132c of the second layer 1132 can be in contact with only a portion of the bottom surface 120b. When the second layer 1132 entirely covers the bottom surface 120b, the depth of the reflective portion 130 formed on the pattern portion 120 can be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process can be formed to be close to the bottom surface 120b, whereby reflective efficiency can be improved due to an increase in the reflection area of the reflective portion 130.

The bank 115 can be extended to cover the inclined surface 1132b of the second layer 1132 covering the inclined surface 120s of the pattern portion 120 while covering the edge of the pixel electrode 114. Therefore, the bank 115 can be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency can be reduced. Therefore, as shown in FIG. 3, each of the second layer 1132 and the bank 115 on the bottom surface 120b of the pattern portion 120 can be discontinuously provided. For example, each of the second layer 1132 and the bank 115 can be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process can be formed to be close to the bottom surface 120b, whereby reflective efficiency can be improved.

Meanwhile, since the bank 115 is provided to be in contact with only a portion of the bottom surface 120b of the pattern portion 120, as shown in FIG. 3, the bank 115 can be disconnected from the pattern portion 120. Since FIG. 3 is a cross-section of FIG. 2, the pattern portion 120 in which the bank 115 is disconnected can be a second pattern line 122. Therefore, the bank 115 can be disconnected from the second pattern line 122. As the bank 115 is disconnected from the second pattern line 122, the reflective portion 130 disposed on the second pattern line 122 can be disposed to be close to the bottom surface 122b of the second pattern line. Therefore, since the reflective portion 130 can be formed as deep as possible in the second pattern line 122 as compared with the case that the bank is not disconnected from the second pattern line, reflection efficiency can be improved. Since the second pattern line 122 is disposed between subpixels SP for emitting different colors, color mixture or color distortion can be prevented from occurring between the subpixels SP for emitting different colors.

In the display apparatus 100 according to one embodiment of the present disclosure, each of the plurality of subpixels SP can include the light extraction portion 140. The light extraction portion 140 can be formed on the overcoat layer 113 (shown in FIG. 3) to overlap the light emission area EA of the subpixel. The light extraction portion 140 can be formed on the overcoat layer 113 of the light emission area EA to have a curved (or uneven) shape, thereby changing a propagation path of light emitted from the light emitting element layer E to increase light extraction efficiency. For example, the light extraction portion 140 can be a non-flat portion, an uneven pattern portion, a micro lens portion, or a light scattering pattern portion.

The light extraction portion 140 can include a plurality of concave portions 141. The plurality of concave portions 141 can be formed to be concave inside the overcoat layer 113. For example, the plurality of concave portions 141 can be formed or configured to be concave from an upper surface 1131a of a first layer 1131 included in the overcoat layer 113. Therefore, the first layer 1131 can include a plurality of concave portions 141. The first layer 1131 can be disposed between the substrate 110 and the light emitting element layer E.

A second layer 1132 of the overcoat layer 113 can be disposed between the first layer 1131 and a light emitting element layer E (or a pixel electrode 114 shown in FIG. 3). The second layer 1132 according to one example can be formed to be wider than the pixel electrode 114 in a first direction (X-axis direction). Thus, the second layer 1132 can partially overlap the light emissive area EA. The upper surface 1132a of the second layer 1132 can be provided flat.

The pixel electrode 114 is formed on the upper surface 1132a of the second layer 1132 provided flat so that the pixel electrode 114 can be provided to be flat, and the organic light emitting layer 116 and the reflective electrode 117, which are formed on the pixel electrode 114, can be provided to be also flat. Since the pixel electrode 114, the organic light emitting layer 116, the reflective electrode 117, for example, the light emitting element layer E is provided to be flat in the light emission area EA, a thickness of each of the pixel electrode 114, the organic light emitting layer 116 and the reflective electrode 117 in the light emission area EA can be uniformly formed. Therefore, the organic light emitting layer 116 can be uniformly emitted without deviation in the light emission area EA.

Further, an upper surface 1132a of the second layer 1132 can be provided to be flat so that the pixel electrode 114 can be provided to be flat, whereby occurrence of a radial rainbow pattern and a radial circular ring pattern due to reflection of external light can be suppressed or minimized as compared with the case that a pixel electrode is formed in a curved shape or an uneven shape.

For example, in case of a display apparatus in which a pixel electrode is provided to be flat, incident external light can be linearly polarized through a polarizing plate and changed to right circularly polarized light while passing through a λ/4 retarder, and the rightly circularly polarized light can be reflected once on the pixel electrode (or the reflective electrode) and changed to left circularly polarized light by a phase change of 180°. The left circularly polarized light can be linearly polarized to be opposite to the incident light while passing through the λ/4 retarder again, and then can become the same as an absorption axis of the polarizing plate and thus can be absorbed into the polarizing plate.

However, in the display apparatus that includes a pixel electrode (or a reflective electrode) formed in a curved shape or an uneven shape, due to curve of the pixel electrode (or the reflective electrode), external light is reflected twice on the pixel electrode (or the reflective electrode) so that a phase is additionally changed as much as 180° as compared with the case that the external light is reflected once, whereby the incident light and the output light have the same phase by passing through the retarder and thus pass through the polarizing plate. Therefore, in the display apparatus that includes a pixel electrode formed in a curved shape or an uneven shape, reflectance of external light can be increased to generate a radial rainbow pattern and a radial circular ring pattern, and black visibility can be deteriorated or black gap can occur.

Therefore, in the display apparatus 100 according to one embodiment of the present disclosure, the upper surface 1132a of the second layer 1132 can be provided to be flat so that the pixel electrode 114 (or a reflective electrode 117) can be provided to be flat, whereby occurrence of a radial rainbow pattern and a radial circular ring pattern due to reflection of external light can be suppressed or minimized as compared with the case that the pixel electrode (or the reflective electrode) is formed in a curved shape or an uneven shape, and real black visibility can be implemented in a non-driving or off state or black gap can be improved.

Further, in the display apparatus 100 according to one embodiment of the present disclosure, since the pixel electrode 114 (or the reflective electrode 117) is provided to be flat so that the external light can be reflected on a lower surface of the pixel electrode 114 (or the reflective electrode 117) once, the polarizing plate can be disposed on the lower surface of the substrate 110 to minimize external light reflection.

Meanwhile, in the display apparatus 100 according to one embodiment of the present disclosure, the light extraction portion 140, which includes the plurality of concave portions 141, can be formed to overlap the light emission area EA, instead of the pixel electrode 114 (or the reflective electrode) being provided to be flat, whereby occurrence of the rainbow pattern and the circular ring pattern can be suppressed and light extraction efficiency of the light emitted from the light emission area can be improved.

In the display apparatus 100 according to one embodiment of the present disclosure, a refractive index of a second layer 1132 can be provided to be greater than that of a first layer 1131. As a result, as shown in FIG. 3, a path of the light emitted from the organic light emitting layer 116 and directed toward the adjacent subpixel SP can be changed toward the reflective portion 130 due to a difference in refractive index between the second layer 1132 and the first layer 1131 of the light extraction portion 140. Therefore, the light having a path formed toward the reflective portion 130 by the light extraction portion 140 can be reflected by the reflective portion 130 and then output toward the light emission area EA of the subpixel SP for emitting light. Hereinafter, the light reflected by the reflective portion 130 and then output to the substrate 110 will be defined as reflective light.

As shown in FIG. 3, the reflective light can include first reflective light L1 (or WG mode extraction light L1) reflected from the reflective portion 130 and emitted to the substrate 110 after being subjected to optical waveguide through total reflection between the pixel electrode 114 and the reflective electrode 117, second reflective light L2 reflected from the reflective portion 130 and emitted to the substrate 110 after its path is changed by the light extraction portion 140, and third reflective light L3 (or substrate mode extraction light L3) primarily reflected by the reflective portion 130 after being emitted from the organic light emitting layer 116, secondarily reflected on a boundary surface between a lower surface of the substrate 110 and an air layer and thirdly reflected by the reflective portion 130 and then emitted to the substrate 110. The first reflective light L1, the second reflective light L2 and the third reflective light L3, which are shown in solid lines in FIG. 3, can be the reflective light extracted by being reflected by the reflective portion 130.

As shown in FIG. 3, the first reflective light L1 according to one example can be emitted from the light emission area EA. The second reflective light L2 can be emitted from a position spaced apart from the light emission area EA. For example, the second reflective light L2 can be emitted from the non-light emission area NEA or a peripheral area. Since a pixel driving line for pixel driving, for example, a data line DL is disposed between the first reflective light L1 and the second reflective light L2, a portion of the light reflected from the reflective portion 130 is covered by the data line DL and thus cannot be emitted toward the substrate 110. Therefore, as shown in FIG. 3, the second reflective light L2 can be emitted toward the substrate 110 from the position spaced apart from the light emission area EA, but is not limited thereto. The first reflective light L1 can be emitted toward the substrate 110 from the position spaced apart from the light emission area EA. The third reflective light L3 can be emitted from the light emission area EA or the non-light emission area NEA.

Meanwhile, the display apparatus 100 according to one embodiment of the present disclosure can further include light which is output to the substrate 110 through the light extraction portion 140 without being reflected by the reflective portion 130. For example, as shown in FIG. 3, the display apparatus 100 can further include first extraction light L4 emitted from the organic light emitting layer 116, refracted on a boundary surface between the plurality of concave portions 141 included in the light extraction portion 140 and the first layer 1131 and then output to the substrate 110, and recycle light L5 (or second extraction light L5) emitted from the organic light emitting layer 116, reflected on the boundary surface between the plurality of concave portions 141 and the first layer 1131 at least once and then secondarily reflected on the lower surface of the pixel electrode 114, refracted on the boundary surface between the plurality of concave portions 141 and the first layer 1131 and output to the substrate 110. Therefore, the display apparatus 100 according to one embodiment of the present disclosure can improve overall light extraction efficiency through the light extraction portion 140 and the reflective portion 130.

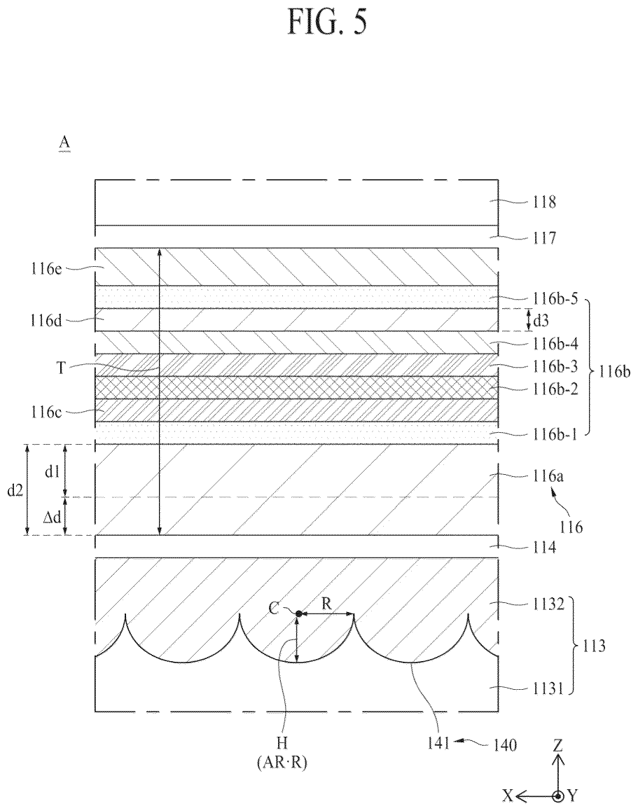

The display apparatus 100 according to one embodiment of the present disclosure is provided so that light efficiency (or maximum light efficiency) of the light emitted from the light emitting layer 116b (or the organic light emitting layer 116) and output to the substrate 110 through the concave portion 141 satisfies an equation such as η_{best}=0.7Δd−2.37 m+97.684, thereby improving light efficiency (or maximum light efficiency) of the light, which is emitted from the light emitting layer 116b and output to the substrate 110 through the concave portion 141, through the shape adjustment of the concave portion 141 and the resonance design adjustment of the light emitting element layer E. This will be described later with reference to FIGS. 5 to 7B.

In the display apparatus 100 according to one embodiment of the present disclosure, since the pattern portion 120 is disposed to surround the light emission area EA, at least a portion of the reflective portion 130 on the pattern portion 120 can be disposed to surround the light emission area EA. Therefore, the reflective light can be emitted toward the substrate 110 from the position spaced apart from the light emission area EA while surrounding at least a portion of the light emission area EA. Therefore, in the display apparatus 100 according to one embodiment of the present disclosure, since light dissipated by waveguide (or optical waveguide) and/or light dissipated by the interface total reflection can be emitted from the non-light emission area NEA in the form of reflective light through the reflective portion 130 surrounding at least a portion of the light emission area EA, light extraction efficiency can be improved and the overall light emission efficiency can be increased.

Hereinafter, a structure of each of the plurality of subpixels SP will be described in detail.

Referring to FIG. 3, the display apparatus 100 according to one embodiment of the present disclosure can further include a buffer layer BL, a circuit element layer, a thin film transistor, a pixel electrode 114, a bank 115, an organic light emitting layer 116, a reflective electrode 117, an encapsulation layer 118 and a color filter CF.

In more detail, each of the subpixels SP according to one embodiment can include a circuit element layer provided on an upper surface of a buffer layer BL, including a gate insulating layer, an interlayer insulating layer 111 and a passivation layer 112, an overcoat layer 113 provided on the circuit element layer, a pixel electrode 114 provided on the overcoat layer 113, a bank 115 covering an edge of the pixel electrode 114, an organic light emitting layer 116 on the pixel electrode 114 and the bank 115, a reflective electrode 117 on the organic light emitting layer 116, and an encapsulation layer 118 on the reflective electrode 117.

The thin film transistor for driving the subpixel SP can be disposed on the circuit element layer. The circuit element layer can be expressed in terms of an inorganic film layer. The pixel electrode 114, the organic light emitting layer 116 and the reflective electrode 117 can be included in the light emitting element layer E.

The buffer layer BL can be formed between the substrate 110 and the gate insulating layer to protect the thin film transistor. The buffer layer BL can be disposed on the entire surface (or front surface) of the substrate 110. The reference line RL for pixel driving can be disposed between the buffer layer BL and the passivation layer 112. The buffer layer BL can serve to block diffusion of a material contained in the substrate 110 into a transistor layer during a high temperature process of a manufacturing process of the thin film transistor. Optionally, the buffer layer BL can be omitted in some cases.

The thin film transistor (or a drive transistor) according to an example can include an active layer, a gate electrode, a source electrode, and a drain electrode. The active layer can include a channel area, a drain area and a source area, which are formed in a thin film transistor area of a circuit area of the subpixel SP. The drain area and the source area can be spaced parallel to each other with the channel area interposed therebetween.

The active layer can be formed of a semiconductor material based on any one of amorphous silicon, polycrystalline silicon, oxide and organic material.

The gate insulating layer can be formed on the channel area of the active layer. As an example, the gate insulating layer can be formed in an island shape only on the channel area of the active layer, or can be formed on an entire front surface of the substrate 110 or the buffer layer BL, which includes the active layer.

The gate electrode can be formed on the gate insulating layer to overlap the channel area of the active layer.

The interlayer insulating layer 111 can be formed to partially overlap the gate electrode and the drain area and source area of the active layer. The interlayer insulating layer 111 can be formed over the entire light emission area where light is emitted in the circuit area and the subpixel SP.

The source electrode can be electrically connected to the source area of the active layer through a source contact hole provided in the interlayer insulating layer overlapped with the source area of the active layer. The drain electrode can be electrically connected to the drain area of the active layer through a drain contact hole provided in the interlayer insulating layer 111 overlapped with the drain area of the active layer.

The drain electrode and the source electrode can be made of the same metal material. For example, each of the drain electrode and the source electrode can be made of a single metal layer, a single layer of an alloy or a multi-layer of two or more layers, which is the same as or different from that of the gate electrode.

In addition, the circuit area can further include first and second switching thin film transistors disposed together with the thin film transistor, and a capacitor. Since each of the first and second switching thin film transistors is provided on the circuit area of the subpixel SP to have the same structure as that of the thin film transistor, its description will be omitted. The capacitor can be provided in an overlap area between the gate electrode and the source electrode of the thin film transistor, which overlap each other with the interlayer insulating layer 111 interposed therebetween.

Additionally, in order to prevent a threshold voltage of the thin film transistor provided in a pixel area from being shifted by light, the display panel or the substrate 110 can further include a light shielding layer provided below the active layer of at least one of the thin film transistor, the first switching thin film transistor or the second switching thin film transistor. The light shielding layer can be disposed between the substrate 110 and the active layer to shield light incident on the active layer through the substrate 110, thereby minimizing a change in the threshold voltage of the transistor due to external light. Further, since the light shielding layer is provided between the substrate 110 and the active layer, the thin film transistor can be prevented from being seen by a user.

The passivation layer 112 can be provided on the substrate 110 to cover the pixel area. The passivation layer 112 covers a drain electrode, a source electrode and a gate electrode of the thin film transistor, and the buffer layer. The reference line can be disposed between the passivation layer 112 and the interlayer insulating layer 111. The reference line can be disposed at a position symmetrical to the pixel power line based on the light emission area EA or a similar position symmetrical to the pixel power line. Therefore, the reference line and the pixel power line can be disposed below the bank 115 without covering the light emitting area EA. The passivation layer 112 can be formed over the circuit area and the light emission area. The passivation layer 112 can be omitted. The color filter CF can be disposed on the passivation layer 112.

The overcoat layer 113 can be provided on the substrate 110 to cover the passivation layer 112 and the color filter CF. When the passivation layer 112 is omitted, the overcoat layer 113 can be provided on the substrate 110 to cover the circuit area. The overcoat layer 113 can be formed in the circuit area in which the thin film transistor is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

The overcoat layer 113 formed in the display area DA (or the light emission area EA) can include a plurality of concave portions 141. The plurality of concave portions 141 are the elements of the light extraction portion 140 for increasing light efficiency of the light emission area EA, and can be formed inside the overcoat layer 113. In detail, as shown in FIG. 5, the plurality of concave portions 141 can be formed in a concave shape on the first layer 1131 of the overcoat layer 113. The plurality of concave portions 141 are provided to be connected to each other so that an embossed shape (or in the form of a plurality of consecutive parabolic) can be formed in the first layer 1131.

The second layer 1132 having a refractive index higher than that of the first layer 1131 can be formed on the first layer 1131. A path of the light, which is directed toward the adjacent subpixel SP, among the light emitted from the light emitting element layer E can be changed toward the reflective portion 130 (or toward the light emission area (EA)) in accordance with a difference in the refractive index between the second layer 1132 and the first layer 1131. The second layer 1132 can be provided to cover the embossed shape (or in the form of a plurality of consecutive parabolic) of the first layer 1131 and thus the upper surface 1132a can be provided to be flat.

The plurality of concave portions 141 can be formed on the first layer 1131 through a photo process using a mask having an opening portion and then a pattern (or etching) or ashing process after the first layer 1131 is coated to cover the passivation layer 111c and the color filter CF. The plurality of concave portions 141 can be formed in an area overlapped with the color filter CF and/or an area that is not overlapped with the bank 115 of the light emission area EA, but are not limited thereto. A portion of the plurality of concave portions 141 can be formed to overlap the bank 115.

Referring back to FIG. 3, the color filter CF disposed in the light emission area EA can be provided between the substrate 110 and the overcoat layer 113. Therefore, the color filter CF can be disposed between the pixel power line, for example, the data line DL and the reflective portion 130 or between the reference line RL and the pattern portion 120. The color filter CF can include a red color filter (or a first color filter) CF1 for converting white light emitted from the organic light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the light emitting layer 116 emits white light.

As shown in FIG. 3, the display apparatus 100 according to one embodiment of the present disclosure can be provided such that color filters having different colors partially overlap each other at a boundary portion of the plurality of subpixels SP. In this case, the display apparatus 100 according to one embodiment of the present disclosure can prevent the light emitted from each subpixel SP from being emitted to the adjacent subpixel SP due to the color filters overlapped with each other at the boundary portion of the subpixels SP, thereby preventing color mixture between the subpixels SP from occurring.

The pixel electrode 114 of the subpixel SP can be formed on the overcoat layer 113. The pixel electrode 114 can be connected to a drain electrode or a source electrode of the thin film transistor through a contact hole passing through the overcoat layer 113 and the passivation layer 112. The edge portion of the pixel electrode 114 can be covered by the bank 115.

Because the display apparatus 100 according to an embodiment of the present disclosure is configured as the bottom emission type, the pixel electrode 114 can be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag. But embodiments of the present disclosure are not limited thereto, and other materials can be used.

Meanwhile, the material constituting the pixel electrode 114 can include MoTi. The pixel electrode 114 can be a first electrode or an anode electrode. But embodiments of the present disclosure are not limited thereto.

The bank 115 is an area from which light is not emitted, and can be provided to surround each of the light emitting portions (or the concave portions 141) of each of the plurality of subpixels SP. For example, the bank 115 can partition (or define) the concave portions 141 of each of the light emitting portion or the subpixels SP. The light emitting portion can mean a portion where the pixel electrode 114 and the reflective electrode 117 are in contact with each of the upper surface and the lower surface of the light emitting layer 116 with the light emitting layer 116 interposed therebetween.

The bank 115 can be formed to cover the edge of each pixel electrode 114 of each of the subpixels SP and expose a portion of each of the pixel electrodes 114. For example, the bank 115 can partially cover the pixel electrode 114. Therefore, the bank 115 can prevent the pixel electrode 114 and the reflective electrode 117 from being in contact with each other at the end of each pixel electrode 114. The exposed portion of the pixel electrode 114, which is not covered by the bank 115, can be included in the light emitting portion (or the light emission area EA). As shown in FIG. 3, the light emitting portion can be formed on the plurality of concave portions 141, and thus the light emitting portion (or the light emission area EA) can overlap the concave portions 141 in a thickness direction (or the third direction (Z-axis direction)) of the substrate 110.

After the bank 115 is formed, the organic light emitting layer 116 can be formed to cover the pixel electrode 114 and the bank 115. Therefore, the bank 115 can be provided between the edge of the pixel electrode 114 and the organic light emitting layer 116. The bank 115 can be expressed as a term of a pixel defining layer. The bank 115 according to one example can include an organic material and/or an inorganic material. As shown in FIG. 3, the bank 114 can be formed to be concave or inclined along the profile of the pattern portion 120 (or the second layer 1132).

Further, with reference to FIG. 3, the display apparatus 100 includes the substrate 110, and the encapsulation layer 118 is on the substrate 110. In this context, the plurality of subpixels SP are located between the encapsulation layer 118 and the substrate 110. Meanwhile, each subpixel (such as SP2) includes the emission area EA and the non-light emission area NEA. Further, an overcoat layer 113 is between the substrate 110 and the plurality of subpixels SP. The overcoat layer 113 includes the concave portion 141 and the second pattern line 122 which are both recessed into the overcoat layer 113. As the concave portions 141 are provided in plural, the concave portions 141 can be referred to as a plurality of first concave portions overlapping the emission area EA. Meanwhile, as the second pattern line 122 is recessed into the overcoat layer 113, the second pattern line 122 can be referred to as a second concave portion overlapping the non-light emission area NEA. The first pattern line 121 can be similarly referred to as a third concave portion overlapping the non-light emission area NEA.

Further, with reference to FIG. 3, the subpixel SP2 includes the light emitting element layer E that includes the pixel electrode 114 and the reflective electrode 117, and the organic light emitting layer 116 disposed between the pixel electrode 114 and the reflective electrode 117. The pixel electrode 114 can be referred to as a first electrode layer on the overcoat layer 113 and overlapping the plurality of first concave portions, and the reflective electrode 117 can be referred to as a second electrode layer on the organic light emitting layer 116.

Further, the plurality of first concave portions can include a curved bottom surface, and the second concave portion can include a planar bottom surface. Accordingly, the bottom surfaces of the first and second concave portions are differently shaped. In addition, a depth of the plurality of first concave portion can be different from a depth of the second concave portion in the overcoat layer 113, but embodiments of the present disclosure are not limited thereto, whereby the depths thereof can be the same.

The overcoat layer 113 includes the first layer 1131 and the second layer 1132. In various embodiments of the present disclosure, the concave portion 141 and the second pattern line 122 can be formed in the first layer 1131. In this instance, the second layer 1132 can include a convex portion that fits into the concave portion 141 of the first layer 1131. In instances where the concave portions of the first layer 1131 is plural, the convex portion of the second layer 1132 is provided in plural, so that a plurality of convex portions of the second layer 1132 can fit into the plurality of concave portions of the first layer 1131, respectively. In this context, the second layer 1132 is interposed between the first layer 1131 and the pixel electrode 114, and there is no direct contact of the pixel electrode 114 and the concave portions 141. But embodiments of the present disclosure are not limited thereto. Further, the second layer 1132 can further include planar or flat portions that have different thicknesses from those of the convex portions.

Hereinafter, the organic light emitting layer 116 of the display apparatus 100 according to one embodiment of the present disclosure will be described in detail with reference to FIG. 5.

FIG. 5 is a schematic enlarged view illustrating an organic light emitting layer in portion A shown in FIG. 3.

Referring to FIGS. 3 and 5, the organic light emitting layer 116 can be formed on the pixel electrode 114 and the bank 115. The organic light emitting layer 116 can be provided between the pixel electrode 114 and the reflective electrode 117. When a voltage is applied to each of the pixel electrode 114 and the reflective electrode 117, an electric field is formed between the pixel electrode 114 and the reflective electrode 117 so that the organic light emitting layer 116 can emit light. The organic light emitting layer 116 can be formed of a plurality of subpixels SP and a common layer provided on the bank 115.

The organic light emitting layer 116 according to one example can be provided to emit white light. As the organic light emitting layer 116 is provided to emit white light, each of the plurality of subpixels SP can include a color filter CF suitable for a corresponding color.

The organic light emitting layer 116 can include a plurality of stacks for emitting light of different colors. For example, the organic light emitting layer 116 can include a lower organic layer 116a, a light emitting layer 116b, a charge generating layer 116c, an upper organic layer 116d and an electron transporting layer (ETL) 116e. The light emitting layer 116b can include a first blue light emitting layer 116b-1 on an upper surface of the lower organic layer 116a, a red light emitting layer 116b-2 on the first blue light emitting layer 116b-1, a yellow-green light emitting layer 116b-3 on the red light emitting layer 116b-2, a green light emitting layer 116b-4 on the yellow-green light emitting layer 116b-3 and a second blue light emitting layer 116b-5 between the green light emitting layer 116b-4 and the reflective electrode 117 (or the electron transporting layer 116e).

The charge generating layer 116c serves to supply charges to the first blue light emitting layer 116b-1 and the red light emitting layer 116b-2. The charge generating layer can include an N-type charge generating layer for supplying electrons to the first blue light emitting layer 116b-1 and a P-type charge generating layer for supplying holes to the red light emitting layer 116b-2. The N-type charge generating layer can include a metal material as a dopant.

Referring to FIG. 5, the organic light emitting layer 116 includes a lower organic layer 116a disposed on an upper surface of the pixel electrode 114, a first blue light emitting layer 116b-1 disposed on an upper surface of the lower organic layer 116a and a charge generating layer 116c disposed on an upper surface of the first blue light emitting layer 116b-1. The red light emitting layer 116b-2, the yellow-green light emitting layer 116b-3 and the green light emitting layer 116b-4 can be disposed on an upper surface of the charge generating layer 116c. The upper organic layer 116d can be disposed on an upper surface of the green light emitting layer 116b-4, a second blue light emitting layer 116b-5 can be disposed on an upper surface of the upper organic layer 116d, and the electron transporting layer 116e can be disposed on an upper surface of the second blue light emitting layer 116b-5. Therefore, as shown in FIG. 5, the reflective electrode 117 can be spaced apart from the pixel electrode 114 as much as the thickness of the organic light emitting layer 116. For example, the thickness of the organic light emitting layer 116 can be an interval between the pixel electrode 114 and the reflective electrode 117. Therefore, the thickness of the organic light emitting layer 116 can be a resonance distance T for forming a micro cavity.

Meanwhile, as shown in FIG. 5, the lower organic layer 116a and the upper organic layer 116d are the thickest layers (or layers occupying the largest portion) of the organic material having a tandem structure for forming the organic light emitting layer 116, and thus can most significantly affect the resonance distance T of the micro cavity.

In the display apparatus 100 according to one embodiment of the present disclosure, a sum of thicknesses of the lower organic layer 116a and the upper organic layer 116d can be equal to or greater than 40% of a thickness between the pixel electrode 114 and the reflective electrode 117. For example, a sum of a thickness d2 of the lower organic layer 116a and a thickness d3 of the upper organic layer 116d can be equal to or greater than 40% of the thickness between the pixel electrode 114 and the reflective electrode 117, for example, the thickness T of the organic light emitting layer 116. When the thickness d2 of the lower organic layer 116a and the thickness d3 of the upper organic layer 116d are smaller than 40% of the thickness between the pixel electrode 114 and the reflection electrode 117, since the resonance distance of the micro cavity is not formed, light efficiency can be deteriorated or little improved. Therefore, in the display apparatus 100 according to one embodiment of the present disclosure, the summed thickness of the lower organic layer 116a and the upper organic layer 116d is equal to or greater than 40% of the thickness between the pixel electrode 114 and the reflective electrode 117, whereby light efficiency can be improved using micro cavity characteristics of light that is emitted.

In the display apparatus 100 according to one embodiment of the present disclosure, each of the lower organic layer 116a and the upper organic layer 116d can be a hole transporting layer HTL.

As shown in FIG. 5, the micro cavity resonance distance T can be determined (or fixed) through a simulation in accordance with a stacked structure of the organic light emitting layer 116 between the pixel electrode 114 and the reflective electrode 117. Therefore, the thickness d2 of the lower organic layer 116a and the thickness d3 of the upper organic layer 116d can be inversely proportional to each other. For example, the thickness d2 of the lower organic layer 116a can be greater than the thickness d3 of the upper organic layer 116d. On the contrary, the thickness d2 of the lower organic layer 116a can be thinner than the thickness d3 of the upper organic layer 116d. The inventor of the display apparatus according to the present disclosure specified the refractive index of the second layer 1132 and then adjusted the thickness d2 of the lower organic layer 116a and the thickness d3 of the upper organic layer 116d to simulate the same, thereby yielding light efficiency η_{best} (or maximum light efficiency) and deriving an equation such as η_{best}=0.7Δd−2.37 m+97.684 based on the light efficiency. Therefore, in the display apparatus 100 according to one embodiment of the present disclosure, light efficiency best (or maximum light efficiency) of the light emitted from the light emitting layer 116b (or the organic light emitting layer 116) and output to the substrate 110 through the concave portion 141 can satisfy the equation such as η_{best}=0.7Δd−2.37 m+97.684. In the equation, ‘Δd’ is a thickness change value of the lower organic layer 116a, and ‘m’ is a hierarchical value of a light efficiency trend with respect to ‘Δd’.

Referring back to FIG. 3, the reflective electrode 117 can be formed on the organic light emitting layer 116. The reflective electrode 117 can be disposed in the light emission area EA and the non-light emission area NEA. The reflective electrode 117 according to one example can include a metal material. The reflective electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

The display apparatus 100 according to one embodiment of the present disclosure is a bottom emission type and has to reflect light emitted from the organic light emitting layer 116 toward the substrate 110, and thus the reflective electrode 117 can be made of a metal material having high reflectance. The reflective electrode 117 according to one example can be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy can be an alloy such as silver (Ag), palladium (Pd) and copper (Cu). But embodiments of the present disclosure are not limited thereto. The reflective electrode 117 can be expressed as terms such as a second electrode, a cathode electrode and a counter electrode.

Meanwhile, in the display apparatus 100 according to one embodiment of the present disclosure, the reflective portion 130 can be a portion of the reflective electrode 117. Therefore, the reflective portion 130 can reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 can be denoted by a reference numeral 117a. In the present disclosure, the reflective portion 130 can mean the reflective electrode 117 that overlaps the pattern portion 120. In particular, the reflective portion 130 can mean the reflective electrode 117 that is inclined while being overlapped with the pattern portion 120. Therefore, as shown in FIG. 3, the reflective portion 130 can reflect light that is directed toward the adjacent subpixel SP, or light that is dissipated through total reflection between interfaces, toward the light emission area EA (or the non-light emission area NEA) of the subpixel SP for emitting light.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 can include at least one inorganic film and at least one organic film.

Meanwhile, as shown in FIG. 3, the encapsulation layer 118 can be disposed not only in the light emission area EA but also in the non-light emission area NEA. The encapsulation layer 118 can be disposed between the reflective electrode 117 and an opposing substrate 200.

FIG. 4A is a schematic view illustrating a light path of a display apparatus not having a light extraction portion 140 (or a plurality of concave portions 141) according to a comparative example, and FIG. 4B is a schematic view illustrating a light path of a display apparatus according to one embodiment of the present disclosure, which as a light extraction portion 140 (or a plurality of concave portions 141).

Referring to FIG. 4A, in case of the display apparatus having no light extraction portion (or concave portion), light extraction efficiency can be reduced as some of the light emitted from a light emitting layer EL is not emitted to the outside due to total reflection on the interface between an electrode E1 and a substrate G and/or between the substrate G and the air layer Air.

In detail, as shown in FIG. 4A, the display apparatus having no light extraction portion can have a structure in which a substrate G, a first electrode E1, a light emitting layer EL and a second electrode E2 are stacked. In this case, the first electrode E1, the light emitting layer EL and the second electrode E2 can correspond to the pixel electrode 114, the organic light emitting layer 116 and the reflective electrode 117 of the display apparatus according to the present disclosure. The substrate G includes layers below the first electrode E1, and can include, for example, at least one of the overcoat layer 113, the passivation layer 112, the interlayer insulating layer 111 or the substrate 110 of the display apparatus according to the present disclosure. As shown in the comparative example of FIG. 4A, light emitted from the light emitting layer EL includes first total reflection light CL1 which is totally reflected on the boundary surface between the first electrode E1 and the substrate G and wave-guided, and second total reflection light CL2 which is totally reflected on the interface between the substrate G and the air layer Air and trapped inside the substrate G. The light can be partially emitted to the outside of the substrate G.

For example, light, which is incident toward the substrate G at a first incident angle θ1, among the light emitted from the light emitting layer EL can be totally reflected at a first emission angle θ1′ opposite to the incident angle on the boundary surface between the substrate G and the air layer Air. The second total reflective light CL2 totally reflected as above can be trapped inside the substrate G and then dissipated. Therefore, as shown in FIG. 4A, the display apparatus having no light extraction portion can deteriorate light efficiency due to the waveguide and the light trapped inside the substrate.

On the other hand, as shown in FIG. 4B, a display apparatus 100 according to one embodiment of the present disclosure can be provided with a light extraction portion 140 including a plurality of concave portions 141 on the lower surface of a second layer 1132. Therefore, the display apparatus 100 of the present disclosure of FIG. 4B can have a structure in which the second layer 1132, the pixel electrode 114, the light emitting layer 116 and the reflective electrode 117 are stacked on the light extraction portion 140. As shown in FIG. 4B, light emitted from the light emitting layer EL can include light that is wave-guided by being totally reflected on the boundary surface between the pixel electrode 114 and the second layer 1132. However, in the display apparatus 100 according to one embodiment of the present disclosure, the plurality of concave portions 141 having a curved shape (or a parabolic shape) are provided on the lower surface of the second layer 1132, so that the lower surface of the second layer 1132 (or the upper surface of the first layer 1131) can be provided in a curved shape (or a parabolic shape) instead of a flat shape. Therefore, in the display apparatus 100 according to one embodiment of the present disclosure, since there is no change in a refractive index from the upper surface of the second layer 1132 to the lower surface of the second layer 1132 (or the upper surface of the first layer 1131) having a curved shape, the light directed toward the plurality of concave portions 141 can be emitted without refraction (or without change of the light path). As shown in FIG. 4B, light, which is emitted in a direction perpendicular to a normal line of the concave portion 141, among the light emitted through the concave portion 141 can be emitted in a straight line shape. The light emitted through the concave portion 141 can be included in the first extraction light L4, or can include first sub-extraction light L4-1 and second sub-extraction light L4-2 as shown in FIG. 4A.

For example, the light L4-1, which is incident toward the concave portion 141 at the first incident angle θ1, among the light emitted from the light emitting layer EL may not be reflected on the boundary surface (or the concave portion 141) between the lower surface of the second layer 1132 having the curved shape (or a parabolic shape) and the air layer Air, and can be emitted to the air layer Air without being refracted in a direction perpendicular to the normal line of the boundary surface. In this case, the first incident angle θ1 can refer to an angle at which light is incident on a vertical virtual line passing through the center of the concave portion 141.

Therefore, as shown in FIG. 4B, the display apparatus 100 according to one embodiment of the present disclosure can further improve light extraction efficiency by minimizing or reducing the light trapped inside the substrate as compared with the display apparatus of the comparative example, which has no light extraction portion (or a plurality of concave portion 141).

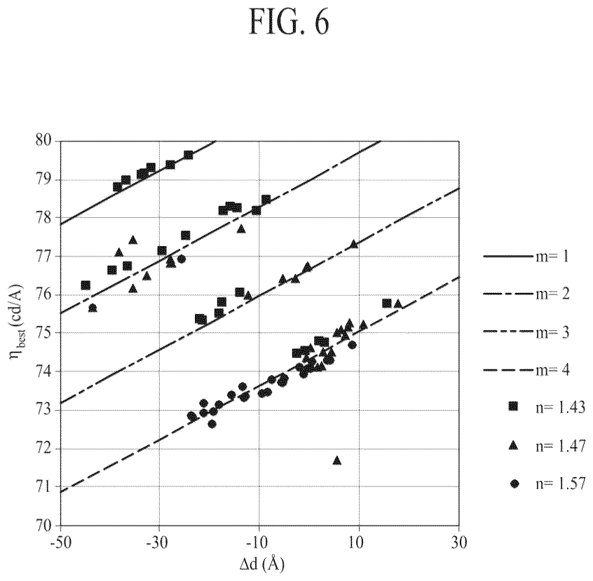

Hereinafter, an equation related to a shape of the concave portion 141 of the light extraction portion 140 and a resonance structure of the light emitting element layer E (or the organic light emitting layer 116) will be described in detail with reference to FIGS. 5 and 6.

FIG. 6 is a simulation graph illustrating light efficiency based on a thickness change of a lower organic layer of a display apparatus according to one embodiment of the present disclosure.

Referring to FIGS. 5 and 6, in the display apparatus 100 according to one embodiment of the present disclosure, light efficiency η_{best} (or maximum light efficiency) of the light emitted from the light emitting layer 116b (or the organic light emitting layer 116) and output to the substrate 110 through the concave portion 141 can satisfy the equation (or Equation 1) such as η_{best}=0.7Δd−2.37 m+97.684. In the equation, ‘Δd’ is a thickness change value of the lower organic layer 116a, and ‘m’ is a hierarchical value of the light efficiency trend with respect to ‘Δd’.

The thickness change value Δd of the lower organic layer 116a is a value obtained by subtracting the thickness of the lower organic layer 116a in the case that the concave portion 141 exists (or the display apparatus according to the present disclosure) from the thickness of the lower organic layer in the case there is no concave portion (or the display apparatus according to the comparative example). For example, as shown in FIG. 5, when the thickness of the lower organic layer of the display apparatus according to the comparative example, which does not include a concave portion, is d1 and the thickness of the lower organic layer 116a of the display apparatus according to the present disclosure, which includes the concave portion 141, is d2, ‘Δd’ can be a value obtained by subtracting d2 from d1. As shown in FIG. 5, since d2 is greater than d1, Δd can have a negative value. For example, when d2 is 1050 Å and d1 is 1000 Å, Δd can be −50 Å. In contrast, when d1 is greater than d2, Δd can have a positive value. For example, when d2 is 970 Å and d1 is 1000 Å, Δd can be 30 Å. When this is applied to the equation 1, light efficiency (or maximum light efficiency) can be more improved in the case that Δd has a positive value than the case that Δd has a negative value.

The hierarchical value ‘m’ of the light efficiency trend for Δd can be determined by a constant M. The constant M can satisfy an equation (or Equation 2) such as M=(R−28 AR+100n)/121. In this equation, ‘R’ is a radius R of the concave portion 141, AR is an aspect ratio AR of the concave portion 141, and ‘n’ is the refractive index of the first layer 1131. As shown in FIG. 5, the aspect ratio AR of the concave portion 141 can be the radius R of the concave portion 141 with respect to a vertical distance H from the center C of the concave portion 141 in the second layer 1132 to the first layer 1131. Therefore, the vertical distance H can be a value obtained by multiplying the aspect ratio AR of the concave portion 141 and the radius R of the concave portion 141. The vertical distance can be a distance from the center C of the concave portion 141 to the upper surface of the first layer 1131 in a direction parallel with a third direction (Z-axis direction).

The inventor of the display apparatus according to the present disclosure specified the refractive index of the second layer 1132 and then simulated light efficiency η_{best} (or maximum light efficiency) while adjusting the refractive index ‘n’ and Δd of the first layer 1131. As a result, the graph of FIG. 6 was obtained.

Referring to FIG. 6, a horizontal axis is a thickness change value Δd of the lower organic layer 116a, and a vertical axis is light efficiency η_{best} (or maximum light efficiency). ‘n’ is the refractive index of the first layer 1131. A solid line is a graph of light efficiency (or maximum light efficiency) according to the thickness change value Δd of the lower organic layer 116a when ‘m’ is 1, and an alternate long and short dash line is a light efficiency (or maximum light efficiency) graph according to the thickness change value Δd of the lower organic layer 116a when ‘m’ is 2. An alternate long and two-short dash line is a light efficiency (or maximum light efficiency) graph according to the thickness change value Δd of the lower organic layer 116a when ‘m’ is 3, and a dotted line is a light efficiency (or maximum light efficiency) graph according to the thickness change value Δd of the lower organic layer 116a when ‘m’ is 4.

The inventor of the display apparatus according to the present disclosure performed simulation while changing the refractive index ‘n’ of the first layer 1131 to 1.43, 1.47 and 1.57. Therefore, as shown in FIG. 6, it can be seen that Y-intercept, for example, light efficiency η_{best} (or maximum light efficiency) is divided into groups (or layers) having four different light efficiency trends, and each group has a constant slope with respect to the thickness change value Δd of the lower organic layer 116a. The inventor of the display apparatus according to the present disclosure derived the equation (or equation 2) such as M=(R−28 AR+100n)/121 based on the graph of FIG. 6. The constant ‘M’ can be calculated by the radius R of the concave portion 141, the aspect ratio AR of the concave portion 141 and the refractive index of the first layer 1131.

The inventor of the display apparatus according to the present disclosure set ‘m’ to 1 when a value calculated by the radius R of the concave portion 141, the aspect ratio AR of the concave portion 141 and the refractive index of the first layer 1131, for example, the constant ‘M’ is 1.00 or less, set ‘m’ to 2 when the constant ‘M’ exceeds 1.00 and is 1.04 or less, set ‘m’ to 3 when the constant ‘M’ exceeds 1.04 and is 1.07 or less and set ‘m’ to 4 when the constant ‘M’ exceeds 1.07. For example, as the constant ‘M’ becomes smaller, ‘m’ was set to be smaller. When the refractive index of the first layer 1131 is constant in the equation 2, the case that the constant ‘M’ is 1 or less can be the case that the radius R of the concave portion 141 is smaller than the aspect ratio AR of the concave portion 141. In this case, the concave portion 141 can be provided in the form of an inverted bell. When the refractive index of the first layer 1131 is constant in the equation 2, the case that the constant ‘M’ exceeds 1 can be the case that the radius R of the concave portion 141 is greater than the curvature AR of the concave portion 141. In this case, the concave portion 141 can be provided in the form of a parabola or bowl, which has a wide width.

In the display apparatus 100 according to one embodiment of the present disclosure, when the shape of the concave portion 141 is provided in a bell shape, since a refractive angle bent to the left or right side from the boundary surface between the first layer 1131 and the second layer 1132 is reduced, front light extraction efficiency can be improved. On the other hand, when the shape of the concave portion 141 is provided in a bowl shape having a wide width, since the refractive angle bent to the left or right from the boundary surface between the first layer 1131 and the second layer 1132 is increased, a luminance viewing angle can be increased.

Meanwhile, as the constant M becomes smaller, ‘m’ becomes smaller proportionally. Therefore, when this applied to equation 1, light efficiency η_{best} (or maximum light efficiency) can have a greater value. In contrast, as the constant M value is increased, ‘m’ is increased in proportion to the constant M. Therefore, when this applied to the equation 1, light efficiency η_{best} (or maximum light efficiency) can have a smaller value. As a result, in the display apparatus 100 according to one embodiment of the present disclosure, when the refractive index ‘n’ of the first layer 1131 and the thickness change value Δd of the lower organic layer 116a have a fixed value, the radius R of the concave portion 141 is formed to be smaller than the aspect ratio AR of the concave portion 141 such that the constant M is reduced, whereby light efficiency η_{best} (or maximum light efficiency) can be further improved. For example, as the concave portion 141 is formed to have a small size while having a bell shape, light efficiency η_{best} (or maximum light efficiency) can be increased.

Meanwhile, as shown in FIG. 6, it can be seen that when the thickness change value Δd of the lower organic layer 116a is −50, the solid line has light efficiency (or maximum light efficiency) of about 77.8, the alternate long and short dash line has light efficiency (or maximum light efficiency) of about 75.6 that is lower than the solid line, the alternate long and two-short dash line has light efficiency (or maximum light efficiency) of about 73.2 that is lower than the alternate long and short dash line, and the dotted line has light efficiency (or maximum light efficiency) of about 70.8 that is lower than the alternate long and two-short dash line. Further, as shown in FIG. 6, it can be seen that the case that the refractive index ‘n’ of the first layer 1131 in each of four groups is 1.43 is positioned at an upper side of the graph as compared with the case that the refractive index ‘n’ of the first layer 1131 is 1.57. Since the upper side of the graph means that light efficiency (or the maximum light efficiency) is further improved, it can be seen that light efficiency (or maximum light efficiency) is further improved as the refractive index ‘n’ of the first layer 1131 is smaller.

Consequently, in the display apparatus 100 according to one embodiment of the present disclosure, the refractive index ‘n’ of the first layer 1131 is formed to be small and the radius R of the concave portion 141 is formed to be smaller than the aspect ratio AR of the concave portion 141, whereby light efficiency η_{best} (or maximum light efficiency) can be maximized.

Meanwhile, in the display apparatus 100 according to one embodiment of the present disclosure, when the shape (or the radius R and the aspect ratio AR of the concave portion 141) of the concave portion 141 and the refractive index ‘n’ of the first layer 1131 are determined, the thickness change value Δd of the lower organic layer 116a is adjusted in accordance with the equation 1, whereby light efficiency η_{best} (or maximum light efficiency) can be improved.

For example, when the shape of the concave portion 141 and the refractive index ‘n’ of the first layer 1131 are determined, the value of ‘m’ becomes a constant in accordance with the equation 2, and according to the equation 1, such as η_{best}=0.7Δd−2.37 m+97.684, light efficiency η_{best} (or maximum light efficiency) can be varied depending on Δd. For example, when the value of Δd is increased, light efficiency η_{best} (or maximum light efficiency) can be increased, and when the value of Δd is reduced, light efficiency η_{best} (or maximum light efficiency) can be reduced. Therefore, the display apparatus 100 according to one embodiment of the present disclosure can be provided so that light efficiency η_{best} (or maximum light efficiency) of the light emitted from the light emitting layer 116b (or the organic light emitting layer 116) and output to the substrate 110 through the concave portion 141 is proportional to the thickness change value of the lower organic layer 116a.

Consequently, in the display apparatus 100 according to one embodiment of the present disclosure, device efficiency of the light emitting element layer E (or the organic light emitting layer 116) can be optimized in accordance with a structural change of a parabolic structure (or the concave portion 141), or the shape of the parabolic structure (or the concave portion 141) can be optimized in accordance with the structure change of the light emitting element layer E (or the organic light emitting layer 116), whereby light efficiency η_{best} (or maximum light efficiency) can be implemented.

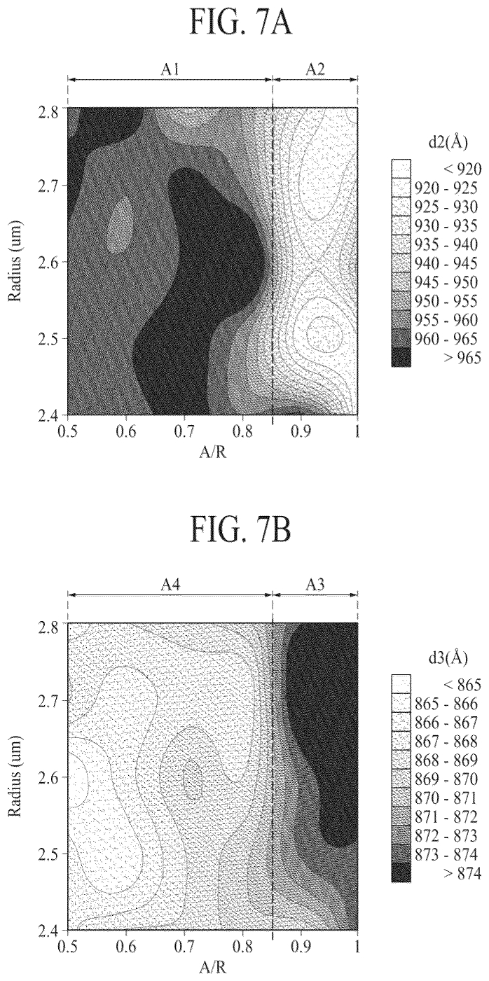

FIG. 7A is a light efficiency map based on a thickness of a lower organic layer, an aspect ratio of a concave portion and a radius of the concave portion of a display apparatus according to one embodiment of the present disclosure, and FIG. 7B is a light efficiency map based on a thickness of an upper organic layer, an aspect ratio of a concave portion and a radius of the concave portion of a display apparatus according to one embodiment of the present disclosure.

The inventor of the display apparatus 100 according to one embodiment of the present disclosure simulated a light efficiency map by adjusting the thickness d2 of the lower organic layer 116a and the radius R and the aspect ratio AR of the concave portion 141, and FIG. 7A illustrates the light efficiency map based on the simulation. In addition, the inventor of the display apparatus 100 according to one embodiment of the present disclosure simulated a light efficiency map by adjusting the thickness d3 of the upper organic layer 116d and the radius R and the aspect ratio AR of the concave portion 141, and FIG. 7B illustrates the light efficiency map based on the simulation.

In each of FIGS. 7A and 7B, it can mean that light efficiency (or maximum light efficiency) is high as shade becomes darker. In each of FIGS. 7A and 7B, a horizontal axis is the aspect ratio AR of the concave portion 141, and a vertical axis is the radius R of the concave portion 141.

First, as shown in FIG. 7A, it can be seen that the light efficiency trend based on the increase in the thickness of the lower organic layer 116a has opposite trends based on the case that the aspect ratio AR of the concave portion 141 is about 0.85. In detail, based on the case that the aspect ratio AR of the concave portion 141 is about 0.85, it is noted from a left area A1 that the thickness d2 of the lower organic layer 116a is high and light efficiency (or maximum light efficiency) is high, and it is noted from a right area A2 that the thickness d2 of the lower organic layer 116a is low and light efficiency (or maximum light efficiency) is low. As described above, since the micro cavity resonant distance T between the pixel electrode 114 and the reflective electrode 117 is a fixed value, the thickness d3 of the upper organic layer 116d can be low when the thickness d2 of the lower organic layer 116a is high.

Referring to and FIG. 7A, it can be seen that when the aspect ratio AR of the concave portion 141 is 0.5 or more and 0.85 or less, more specifically 0.65 or more and 0.75 or less and the radius R of the concave portion 141 is 2.4 um or more and 2.53 um or less, light efficiency (or maximum light efficiency) is maximized. In this case, the thickness d2 of the lower organic layer 116a can be greater than 965 Å.

Therefore, the display apparatus 100 according to one embodiment of the present disclosure is provided so that the thickness d2 of the lower organic layer 116a is thicker than the thickness d3 of the upper organic layer 116d and the aspect ratio AR of the concave portion 141 is 0.5 or more and 0.85 or less, whereby light efficiency (or maximum light efficiency) can be further improved as compared with the case that the thickness d2 of the lower organic layer 116a is thinner than the thickness d3 of the upper organic layer 116d.

Next, as shown in FIG. 7B, it can be seen that the light efficiency trend based on the increase in the thickness of the upper organic layer 116d has opposite trends based on the case that the aspect ratio AR of the concave portion 141 is about 0.85. In detail, based on the case that the aspect ratio AR of the concave portion 141 is about 0.85, it is noted from a left area A4 that the thickness d3 of the upper organic layer 116d is low and light efficiency (or maximum light efficiency) is low, and it is noted from a right area A3 that the thickness d3 of the upper organic layer 116d is high and light efficiency (or maximum light efficiency) is high. As described above, since the micro cavity resonant distance T is a fixed value, the thickness d2 of the lower organic layer 116a can be low when the thickness d3 of the upper organic layer 116d is high.

Referring to and FIG. 7B, it can be seen that when the aspect ratio AR of the concave portion 141 is 0.85 or more and 1 or less, more specifically 0.95 or more and 1 or less and the radius R of the concave portion 141 is 2.52 um or more and 2.8 um or less, light efficiency (or maximum light efficiency) is maximized. In this case, the thickness d3 of the upper organic layer 116d can be greater than 874 Å.

Therefore, the display apparatus 100 according to one embodiment of the present disclosure is provided so that the thickness d3 of the upper organic layer 116d is thicker than the thickness d2 of the lower organic layer 116a and the aspect ratio AR of the concave portion 141 is 0.85 or more and 1 or less, whereby light efficiency (or maximum light efficiency) can be further improved as compared with the case that the thickness d3 of the upper organic layer 116d is thinner than the thickness d2 of the lower organic layer 116a.

In case of FIG. 7A, since the aspect ratio AR of the concave portion 141 is 0.5 or more and 0.85 or less, the concave portion 141 can be provided in the form of a bowl having a wide width. In case of FIG. 7B in which the aspect ratio AR of the concave portion 141 is 0.85 or more and 1 or less, the concave portion 141 can be provided in the form of an inverted bell. Therefore, the concave portion 141 can be more easily formed in the display apparatus according to FIG. 7A in which the concave portion 141 is provided in the form of a bowl than in the display apparatus according to FIG. 7B in which the concave portion 141 is provided in the form of an inverted bell.

Therefore, the display apparatus 100 according to one embodiment of the present disclosure is provided so that the thickness d2 of the lower organic layer 116a is thicker than the thickness d3 of the upper organic layer 116d and the aspect ratio AR of the concave portion 141 is 0.5 or more and 0.85 or less, whereby light efficiency (or maximum light efficiency) can be further improved as compared with the case that the thickness d2 of the lower organic layer 116a is thinner than the thickness d3 of the upper organic layer 116d.

Consequently, the display apparatus 100 according to one embodiment of the present disclosure can improve light efficiency (or maximum light efficiency) of the light emitted from the light emitting layer 116b (or the organic light emitting layer 116) and output to the substrate 110 through the concave portion 141 by optimizing the shape of the concave portion 141 and the resonance design of the light emitting element layer E. In detail, the display apparatus 100 according to one embodiment of the present disclosure can improve light efficiency (or maximum light efficiency) of the light emitted from the light emitting layer 116b (or the organic light emitting layer 116) and output to the substrate 110 through the concave portion 141 by optimizing the aspect ratio AR of the concave portion 141, the radius R of the concave portion 141 and the thickness of the lower organic layer 116a which most significantly affects formation of the resonance distance.

According to the present disclosure, the following advantageous effects can be obtained.

The display apparatus according to the present disclosure is provided so that each of the plurality of subpixels includes a plurality of concave portions, whereby light extraction efficiency of the light emitted from the light emitting element layer can be improved.

The display apparatus according to the present disclosure can maximize light extraction efficiency of the light emitted from the light emitting element layer by adjusting or controlling the thickness of the lower organic layer (or hole transporting layer) included in the light emitting layer and the shape of the concave portion (or light extraction portion).

In the display apparatus according to the present disclosure, the reflective portion is provided on the pattern portion that is in the periphery of the non-light emission area between the plurality of subpixels, so that the light can be extracted even from the non-light emission area, whereby overall light efficiency can be improved.

In the display apparatus according to the present disclosure, since the light can be extracted even from the non-light emission area, the display apparatus according to the present disclosure can have the same light emission efficiency or more improved light emission efficiency even with low power, whereby overall power consumption can be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus comprising:
at least one pixel on a substrate, and including a plurality of subpixels;
a pattern portion disposed on the substrate and formed to be concave between the plurality of subpixels; and
a reflective portion on the pattern portion,
wherein the plurality of subpixels include a first layer including a plurality of concave portions adjacent to the reflective portion and an organic light emitting layer having a lower organic layer on the first layer and a light emitting layer on the lower organic layer, and
wherein light efficiency of light emitted from the light emitting layer and output to the substrate through a concave portion of the plurality of concave portions is proportional to a thickness change value of the lower organic layer.

2. The display apparatus of claim 1, wherein the light efficiency (η_{best}) of light emitted from the light emitting layer and output to the substrate through the concave portion satisfies a following equation:
η_{best}=0.7Δd−2.37m+97.684,
where Δd is a thickness change value of the lower organic layer, and ‘m’ is a hierarchical value of a light efficiency trend with respect to Δd.

3. The display apparatus of claim 2, wherein the thickness change value of the lower organic layer is a value obtained by subtracting a thickness of the lower organic layer when there is the concave portion from a thickness of the lower organic layer when there is no concave portion.

4. The display apparatus of claim 2, wherein the hierarchical value ‘m’ of the light efficiency trend with respect to Δd is determined by a constant M,
the constant M satisfies M=(R−28 AR+100n)/121,
where ‘R’ is a radius of the concave portion, AR is an aspect ratio of the concave portion, and ‘n’ is a refractive index of the first layer.

5. The display apparatus of claim 4, wherein the plurality of subpixels include a second layer on the first layer, and the aspect ratio of the concave portion is the radius of the concave portion with respect to a vertical distance from the center of the concave portion in the second layer to the first layer.

6. The display apparatus of claim 4, wherein ‘m’ is 1 when the constant M is 1.00 or less, ‘m’ is 2 when the constant M exceeds 1.00 and is 1.04 or less, ‘m’ is 3 when the constant M exceeds 1.04 and is 1.07 or less, and ‘m’ is 4 when the constant M exceeds 1.07.

7. The display apparatus of claim 5, wherein the plurality of subpixels include a light emission area overlapped with the plurality of concave portions, having a light emitting element layer, and a non-light emission area adjacent to the light emission area,
the light emitting element layer includes a pixel electrode between the second layer and the lower organic layer in the light emission area, and a reflective electrode on the light emitting layer and in the light emission area and the non-light emission area, and
the reflective portion is a portion of the reflective electrode.

8. The display apparatus of claim 7, wherein the second layer partially overlaps the light emission area, and an upper surface of the second layer is flat.

9. The display apparatus of claim 7, wherein the light emitting layer includes:
a first blue light emitting layer on an upper surface of the lower organic layer;
a red light emitting layer on the first blue light emitting layer;
a yellow-green light emitting layer on the red light emitting layer;
a green light emitting layer on the yellow-green light emitting layer; and
a second blue light emitting layer between the green light emitting layer and the reflective electrode.

10. The display apparatus of claim 9, wherein the organic light emitting layer includes:
a charge generating layer between the first blue light emitting layer and the red light emitting layer;
an upper organic layer between the green light emitting layer and the second blue light emitting layer; and
an electron transporting layer between the second blue light emitting layer and the reflective electrode, and
a summed thickness of the lower organic layer and the upper organic layer is equal to or greater than 40% of a thickness between the pixel electrode and the reflective electrode.

11. The display apparatus of claim 10, wherein each of the lower organic layer and the upper organic layer is a hole transporting layer.

12. The display apparatus of claim 10, wherein the thickness of the lower organic layer and the thickness of the upper organic layer are inversely proportional to each other.

13. The display apparatus of claim 10, wherein the thickness of the lower organic layer is greater than that of the upper organic layer, and the aspect ratio of the concave portion is 0.5 or more and 0.85 or less.

14. The display apparatus of claim 10, wherein the thickness of the upper organic layer is greater than that of the lower organic layer, and the aspect ratio of the concave portion is 0.85 or more and 1 or less.

15. The display apparatus of claim 5, wherein the refractive index of the first layer is smaller than that of the second layer.

16. The display apparatus of claim 1, wherein the pattern portion has a width reduced from the reflection portion toward the substrate.

17. The display apparatus of claim 7, wherein the pattern portion is formed to be concave in the first layer and surrounds the light emission area in the form of a slit or a trench.

18. The display apparatus of claim 7, wherein the pattern portion includes a bottom surface and an inclined surface connected to the bottom surface,
the bottom surface of the pattern portion is disposed to be closer to the substrate than the pixel electrode, and
the inclined surface of the pattern portion surrounds the plurality of concave portions.

19. The display apparatus of claim 18, further comprising a bank covering an edge of the pixel electrode,
wherein the second layer is in contact with the bottom surface while partially covering the inclined surface of the pattern portion, and
the bank is in contact with a portion of the bottom surface of the pattern portion while covering the second layer covering the inclined surface.

20. The display apparatus of claim 19, wherein each of the second layer and the bank on the bottom surface of the pattern portion is discontinuous.

21. A display apparatus comprising:
an encapsulation layer on a substrate;
a plurality of subpixels between the encapsulation layer and the substrate, each subpixel including an emission area and a non-light emission area; and
an overcoat layer between the substrate and the plurality of subpixels, and including a plurality of first concave portions overlapping the emission area and a second concave portion overlapping the non-light emission area.

22. The display apparatus of claim 21, wherein the each subpixel further includes:
a first electrode layer on the overcoat layer and overlapping the plurality of first concave portions;
a light emitting layer on the first electrode layer; and
a second electrode layer on the light emitting layer.

23. The display apparatus of claim 21, wherein the plurality of first concave portions include a curved bottom surface, and the second concave portion includes a planar bottom surface.

24. The display apparatus of claim 21, wherein the overcoat layer includes a first overcoat layer and a second overcoat layer on the first overcoat layer,
wherein the plurality of first concave portions and the second concave portion are included in the first overcoat layer, and
wherein the second overcoat layer includes a plurality of convex portions that fits into the plurality of first concave portions, respectively.
